(19) United States
(12) Patent Application Publication
(10) Pub. No.: US 2026/0068257 A1
(43) Pub. Date: Mar. 5, 2026

(54) PHOTORESIST POISONING REDUCTION

(71) Applicant: TEXAS INSTRUMENTS INCORPORATED, Dallas, TX (US)

(72) Inventors: Jackson Bauer, Rowlett, TX (US); Abbas Ali, Plano, TX (US); Pushpa Mahalingam, Richardson, TX (US); Ravi Natarajan, Lucas, TX (US); Richard Andrianarison, Plano, TX (US)

(21) Appl. No.: 18/819,132

(22) Filed: Aug. 29, 2024

(51) Int. Cl. H01L 29/66; H01L 21/02; H01L 21/266; H01L 29/78

(52) U.S. Cl. CPC H10D 64/021; H10D 30/60

(57) ABSTRACT

The present disclosure generally relates to semiconductor processing for forming a semiconductor device. In an example, semiconductor device includes a semiconductor substrate, a nitride structure, and an oxide layer. The nitride structure is over the semiconductor substrate. The oxide layer is on the nitride structure. The semiconductor substrate includes an implanted doped region laterally proximate the nitride structure and the oxide layer. In another example, a nitride structure is formed over a semiconductor substrate. An oxide layer is formed on the nitride structure. A photoresist is formed over the semiconductor substrate. The photoresist has an opening exposing at least a portion of the oxide layer on the nitride structure. An implantation is performed using the photoresist to form an implanted doped region in the semiconductor substrate.

### BACKGROUND

In integrated circuits (ICs), various semiconductor devices have components formed in or on a semiconductor substrate. Semiconductor devices commonly implement PN junctions formed in the semiconductor substrate. PN junctions may be formed by a p-type doped region being proximate an n-type doped region in the semiconductor substrate. Proper formation of these doped regions is needed for proper functionality of the semiconductor device that includes the PN junction formed by the doped regions.

### SUMMARY

An example is a semiconductor device. The semiconductor device includes a semiconductor substrate, a nitride structure, and an oxide layer. The nitride structure is over the semiconductor substrate. The oxide layer is on the nitride structure. The semiconductor substrate includes an implanted doped region laterally proximate the nitride structure and the oxide layer.

Another example is a method. A nitride structure is formed over a semiconductor substrate. An oxide layer is formed on the nitride structure. A photoresist is formed over the semiconductor substrate. The photoresist has an opening exposing at least a portion of the oxide layer on the nitride structure. An implantation is performed using the photoresist to form an implanted doped region in the semiconductor substrate.

A further example is a method. A gate electrode is formed over a semiconductor substrate. A nitride gate spacer is formed over the semiconductor substrate and along a sidewall of the gate electrode. An oxide layer is formed on the nitride gate spacer. A photoresist is formed over the semiconductor substrate. The photoresist has an opening exposing at least a portion of the oxide layer on the nitride gate spacer. A source/drain region is formed in the semiconductor substrate. Forming the source/drain region includes performing an implantation of a dopant into the semiconductor substrate using the photoresist.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a flow chart of a method for manufacturing a semiconductor device according to some examples.

FIGS. 2, 3, 4, 5, 6, and 7 are respective cross-sectional views of a semiconductor device in intermediate stages of manufacturing according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for forming a semiconductor device. In some examples, a nitride structure is formed over a semiconductor substrate, and an oxide layer is formed on the nitride structure. The oxide layer may be formed using an ash process, a thermal oxidation process, and/or a deposition process. A photoresist is formed over the semiconductor substrate and is patterned to have an opening exposing at least a portion of the oxide layer on the nitride structure. An implantation is performed using the photoresist (e.g., as a mask) to form an implanted doped region in the semiconductor substrate. Hence, a semiconductor device, such as a field effect transistor (FET), may include a nitride structure over a semiconductor substrate and an oxide layer on the nitride structure. The semiconductor substrate includes an implanted doped region laterally proximate to the nitride structure and the oxide layer.

According to some examples, by forming an oxide layer on a nitride structure prior to forming the photoresist, poisoning of the photoresist by amines outgassing from the nitride structure may be reduced or prevented, which may reduce or prevent formation of a scum layer where an opening (proximate to the nitride structure) in the photoresist is formed. Reducing or avoiding formation of a scum layer may permit a target doping profile (including concentration) of the implanted dopant to be more precisely achieved as intended, which, in some examples, may provide a desired drain-to-source on resistance (R_{DSON}) for a FET—e.g., avoiding a greater R_{DSON} than desired. Other benefits and advantages may be achieved.

Various examples are described subsequently. Although the specific examples may illustrate various aspects of the above generally described features, examples may incorporate any combination of the above generally described features (which are described in more detail in examples below).

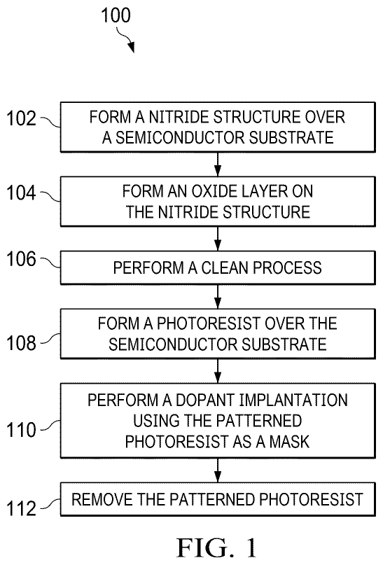

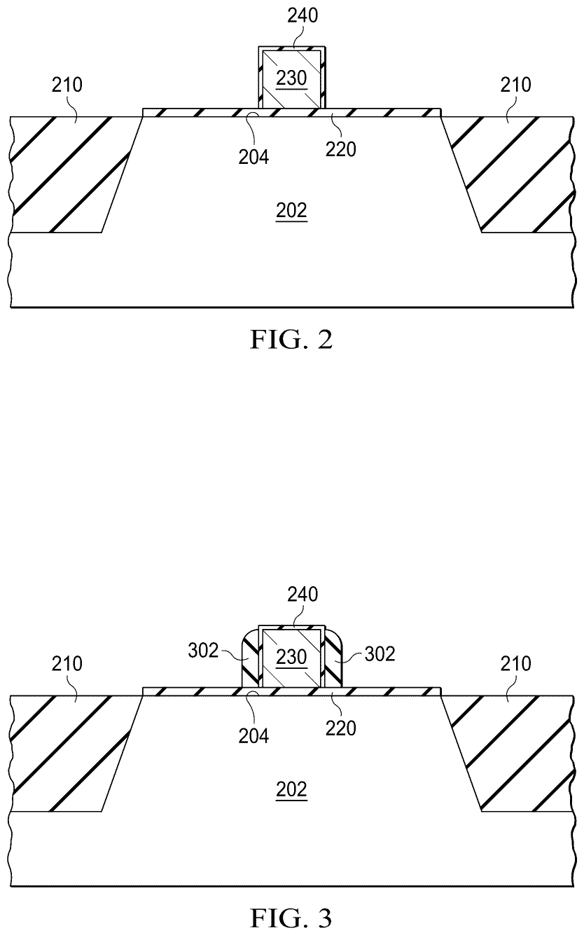

FIG. 1 is a flow chart of a method 100 for manufacturing a semiconductor device according to some examples. FIGS. 2 through 7 are respective cross-sectional views of a semiconductor device in intermediate stages of manufacturing according to some examples. The method 100 of FIG. 1 is described herein in the context of FIGS. 2 through 7. The semiconductor device manufactured according to the intermediate stages of FIGS. 2 through 7 includes a FET. In other examples, a different semiconductor device may be manufactured.

Referring to FIG. 2, a semiconductor substrate 202 is provided. The semiconductor substrate 202 may be or include a bulk semiconductor substrate, a semiconductor-on-insulator (SOI) substrate, or any other appropriate substrate. The semiconductor substrate 202 may also include a support (or handle) substrate and an epitaxial layer epitaxially grown on the support substrate. In some examples, the semiconductor substrate 202 is or includes a silicon substrate (which may be singulated from a bulk silicon wafer at the conclusion of semiconductor processing). In further examples, the semiconductor substrate 202 includes a silicon substrate with an epitaxial silicon layer grown thereon. The semiconductor substrate 202 is or includes a semiconductor material in and/or on which devices, such as a p-channel FET (pFET) and/or an n-channel FET (nFET), are formed. In some examples, the semiconductor material is or includes silicon (Si), silicon germanium (SiGe), gallium arsenide (GaAs), gallium nitride (GaN), the like, or a combination thereof. The semiconductor substrate 202 has an upper surface 204 in and/or on which devices (e.g., a pFET and/or an nFET) are formed. In the illustrated example, the semiconductor material of the semiconductor substrate 202 is p-doped with a p-type dopant. In some examples, the semiconductor substrate 202 is p-doped with a p-type dopant (e.g., boron (B)) with a concentration in a range from 1×10¹⁴ cm⁻³ to 1×10¹⁵ cm⁻³. Another dopant type and/or other doping concentrations may be implemented.

Isolation structures 210 are formed in the semiconductor substrate 202. In the illustrated example, the isolation structures 210 are shallow trench isolation structures (STIs) extending from the upper surface 204 of the semiconductor substrate 202 into the semiconductor substrate 202. In the illustrated example, the isolation structures 210 may have respective upper surfaces co-planar with the upper surface 204 of the semiconductor substrate 202. In other examples, the isolation structures 210 may have respective upper surfaces above and/or may be below the upper surface 204 of the semiconductor substrate 202. The isolation structures 210 may include, for example, a liner layer, such as including silicon oxide or silicon nitride, conformally along surfaces of a respective trench in the semiconductor substrate 202 and a fill isolation material, such as silicon oxide, over and on the liner layer.

The isolation structures 210 may be formed by depositing a hardmask layer over the semiconductor substrate 202. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 202 using the patterned hardmask layer as a mask. The liner layer may then be conformally formed or deposited in the recesses or trenches and may be deposited over the patterned hardmask layer, such as by an oxidation process, plasma enhanced CVD (PECVD), or the like. The fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by the planarization process and/or an etch selective to the hardmask layer, which may be a wet etch process. In other examples, the isolation structures 210 may be field oxide structures, such as local oxidation of silicon (LOCOS) structures, at the upper surface 204 of the semiconductor substrate 202, which may be formed using a LOCOS process.

The isolation structures 210 laterally define an active area of the upper surface 204 of the semiconductor substrate 202 on which a FET (e.g., a pFET and/or an nFET) is to be formed. Respective isolation structures 210 laterally encircle the active area of the upper surface 204 of the semiconductor substrate 202 on which the FET is to be formed, as indicated subsequently.

For forming a pFET, a well implantation may be performed. A well may be formed by the well implantation. For example, an n-type doped well may be formed. An n-type doped well may be formed by masking (e.g., by a photoresist using photolithography) areas of the semiconductor substrate 202 where an n-type doped well is not to be formed and implanting n-type dopants into the semiconductor substrate 202. An n-type doped well may extend from the upper surface 204 of the semiconductor substrate 202 into a depth in the semiconductor substrate 202, which may be to a level below, at, or above a bottom surface of the isolation structures 210. The isolation structures 210 may generally laterally define the n-type doped well. A concentration of the n-type dopant of the n-type doped well may be greater than a concentration of the p-type dopant of the p-type doped semiconductor substrate 202. In some examples, the n-type doped well may be doped with an n-type dopant (e.g., phosphorus (P) or arsenic (As)) with a concentration in a range from 1×10¹⁵ cm⁻³ to 1×10¹⁷ cm⁻³. Other doping concentrations and/or dopant type may be implemented for the doped well.

A gate dielectric layer 220 is formed over and on the semiconductor substrate 202. The gate dielectric layer 220 may be or include silicon oxide, silicon nitride, or another dielectric layer. In the illustrated example, the gate dielectric layer 220 is an oxide layer formed, for example, by an oxidation process, such as in situ steam generation (ISSG) oxidation, thermal oxidation, or another oxidation process. In other examples, the gate dielectric layer 220 may be formed by a deposition process, such as by CVD, atomic layer deposition (ALD), or another deposition process.

A gate electrode 230 is formed over and on the gate dielectric layer 220. The gate electrode 230 may be or include any conductive material, such as a metal, a doped semiconductor material, the like, or a combination thereof. A layer of a material of the gate electrode 230 may be formed over the gate dielectric layer 220. The layer of the material of the gate electrode 230 may be deposited over the gate dielectric layer 220 using any deposition process, such as CVD or the like. In some examples, the gate electrode 230 is or includes a semiconductor material, such as polycrystalline silicon (polysilicon), and in such some examples, the semiconductor material may be doped in situ during deposition and/or may be implanted by a dopant after deposition (e.g., during implantation to form source/drain regions). In some examples, the gate electrode 230 is polysilicon that is p-type doped with a p-type dopant (e.g., for a pFET) or is n-type doped with an n-type dopant (e.g., for an nFET) with a concentration in a range from 1×10¹⁹ cm⁻³ to 1×10²¹ cm⁻³. A hardmask layer may be formed over the layer of the material of the gate electrode 230, e.g., for subsequent patterning. In some examples, the hardmask layer may be or include silicon nitride deposited by CVD, although other hardmask (e.g., dielectric) materials and/or other deposition processes may be used in other examples. The layer of the material of the gate electrode 230 may then be patterned into the gate electrode 230. In some examples, the hardmask layer is patterned corresponding to the pattern of the gate electrode 230, and using the patterned hardmask layer as a mask, the gate electrode 230 is patterned. The hardmask layer may be patterned using appropriate photolithography and etching processes, and the gate electrode 230 may be patterned using an appropriate etching process. For example, an anisotropic etch, such as an RIE, may be implemented. The hardmask layer may be removed, such as by an etch selective to the material of the hardmask layer and/or a wet strip process.

A reoxidation layer 240, as illustrated, is formed on exposed surfaces of the gate electrode 230, such as when the gate electrode 230 includes a semiconductor material (e.g., polysilicon). In some examples, the reoxidation layer 240 may be omitted. The reoxidation layer 240 may be formed by an oxidation process, such as ISSG oxidation, thermal oxidation, or another oxidation process. The reoxidation layer 240 may remove surface damage of the gate electrode 230 resulting from patterning the gate electrode 230.

Although not illustrated, lightly doped drain (LDD) regions may be formed in the semiconductor substrate 202. The LDD regions may be formed in the semiconductor substrate 202 on laterally opposing sides of the gate electrode 230. The LDD regions may be formed by masking (e.g., by a photoresist using photolithography) regions where LDD regions are not to be formed and implanting a p-type dopant (e.g., for a pFET) or an n-type dopant (e.g., for an nFET) into the semiconductor substrate 202. The gate electrode 230 may also be implanted with the dopant and acts as a mask to prevent implantation of the dopant in at least some portions of the semiconductor substrate 202 underlying the gate electrode 230. A concentration of the p-type or n-type dopant of the LDD regions may be greater than a concentration of the p-type dopant of the p-type doped semiconductor substrate 202 and, if an n-type doped well is implemented for a pFET, may be greater than a concentration of the n-type dopant of the n-type doped well. In some examples, the LDD regions may be doped with a p-type or n-type dopant with a concentration in a range from 1×10¹⁶ cm⁻³ to 1×10¹⁹ cm⁻³.

Referring to block 102 of FIG. 1 and to FIG. 3, a nitride structure is formed over the semiconductor substrate 202. The nitride structure in the example of FIG. 3 includes nitride gate spacers 302. The nitride gate spacers 302 are formed on or along respective sidewalls of the gate electrode 230 (e.g., on the reoxidation layer 240). The nitride gate spacers 302 may be formed by depositing a layer of nitride (e.g., silicon nitride) of the nitride gate spacers 302 conformally over the semiconductor substrate 202 and anisotropically etching the layer of nitride such that the nitride gate spacers 302 remain. The material of the nitride gate spacers 302 may be any appropriate nitrogen-containing dielectric material, such as silicon nitride, silicon oxynitride, the like, or a combination thereof. In some examples, the nitride gate spacers 302 may be any material that may outgas amines (e.g., R₂—NH or R₃—N). The layer may be deposited by CVD, PECVD, ALD, or the like. Other nitride structures may be formed, including by different processes.

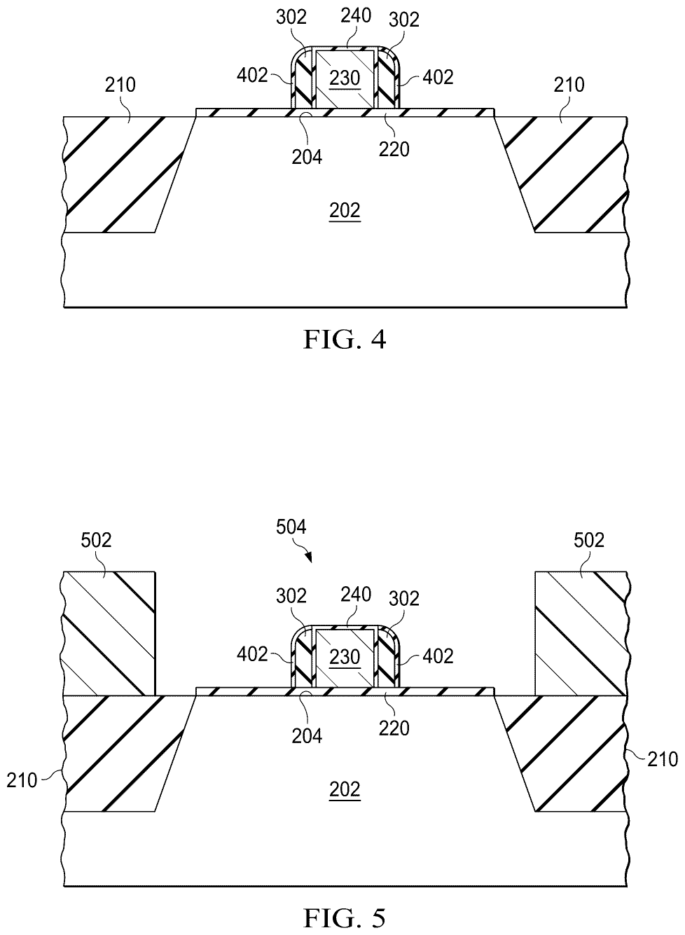

Referring to block 104 of FIG. 1 and to FIG. 4, an oxide layer is formed on the nitride structure. The oxide layer in the example of FIG. 4 includes an oxide layer 402. The oxide layer 402 is formed on exposed surfaces of the nitride gate spacers 302, which generally face away from the gate electrode 230. In some examples, the oxide layer (e.g., the oxide layer 402) may be formed by an oxidation process and/or a deposition process. In some examples, the oxidation process may be or include an ash process and/or a thermal oxidation process. In some examples, the deposition process may be or include an ALD, a CVD, or the like. The oxide layer (e.g., the oxide layer 402) may passivate the nitride structure (e.g., the nitride gate spacers 302), which may reduce or prevent amines from outgassing from the nitride structure. Reducing or preventing amines from outgassing from the nitride structure may reduce or prevent photoresist poisoning by such amines during a photolithography process, such as illustrated subsequently.

An ash process for forming the oxide layer may oxidize exposed surfaces of the nitride structure. The ash process may include flowing oxygen (O₂) gas in a plasma. In some examples, an ash process in a process chamber includes, sequentially, a pre-ash stabilization step, a plasma strike step, a main ash step, a passivation step, and a post-ash stabilization step. Although an example ash process is described herein, other ash processes (including different process parameters) may be implemented in other examples.

In the pre-ash stabilization step, a pressure in the process chamber is in a range from 250 milliTorr (mtorr) to 3,000 mtorr, such as 2,000 mtorr. A flow rate of oxygen (O₂) gas is in a range from 500 standard cubic centimeter per minute (sccm) to 10,000 sccm, such as 8,000 sccm. No plasma is generated in the process chamber in the pre-ash stabilization step.

In the plasma strike step, a pressure in the process chamber is in a range from 250 mtorr to 3,000 mtorr, such as 350 mtorr. A flow rate of oxygen (O₂) gas is in a range from 250 sccm to 10,000 sccm, such as 2,000 sccm, and a flow rate of a mixture gas including nitrogen (N₂) gas and hydrogen (H₂) gas is in a range up to 8,000 sccm, such as 500 sccm. A plasma is generated in the process chamber in the plasma strike step with a radio-frequency (RF) power in a range from 250 Watts (W) to 1,000 W, such as 600 W.

In the main ash step, a pressure in the process chamber is in a range from 1,000 mtorr to 3,000 mtorr, such as 1,500 mtorr. A flow rate of oxygen (O₂) gas is in a range from 1,000 sccm to 10,000 sccm, such as 7,825 sccm, and a flow rate of the mixture gas including nitrogen (N₂) gas and hydrogen (H₂) gas is in a range up to 8,000 sccm, such as 1,175 sccm. A plasma is maintained in the process chamber in the main ash step with an RF power in a range from 1,000 W to 3,000 W, such as 2,500 W.

In the passivation step, a pressure in the process chamber is in a range from 1,000 mtorr to 3,000 mtorr, such as 1,500 mtorr. A flow rate of oxygen (O₂) gas is in a range up to 1,000 sccm, such as 750 sccm, and a flow rate of the mixture gas including nitrogen (N₂) gas and hydrogen (H₂) gas is in a range from 2,000 sccm to 10,000 sccm, such as 5,000 sccm. A plasma is maintained in the process chamber in the passivation step with an RF power in a range from 1,000 W to 3,000 W, such as 2,500 W.

In the post-ash stabilization step, a pressure in the process chamber is in a range from 500 mtorr to 2,000 mtorr, such as 1,000 mtorr. A flow rate of oxygen (O₂) gas is in a range from 1,000 sccm to 10,000 sccm, such as 8,000 sccm. The plasma in the process chamber is ceased in the post-ash stabilization step.

Referring to block 106 of FIG. 1, a clean process is performed. Any appropriate clean process may be implemented. In some examples, the clean process includes a sulfuric acid (H₂SO₄) and peroxide (H₂O₂) mixture (SPM) followed by an RCA clean 1 (SC1). A ratio of sulfuric acid to peroxide in the SPM may be in a range from 3:1 to 7:1. The SPM may be performed for a duration in a range from 3 minutes to 10 minutes, such as 4 minutes. The SC1 includes a mixture of deionized water (H₂O), ammonia (NH₃), and peroxide (H₂O₂). As an example, a ratio of deionized water (H₂O) to ammonia (NH₃) to peroxide (H₂O₂) may be 20:1:1 (H₂O:NH₃:H₂O₂). In some examples, the SC1 may be a cold SC1, such as at a temperature equal to or less than 27° C., such as in a range from 21° C. to 27° C. (e.g., room temperature (23° C.)). In some examples, the SC1 may be a hot SC1, such as at a temperature equal to or greater than 50° C. The SC1 may be performed for a duration in a range from 3 minutes to 10 minutes, such as 5 minutes.

In some examples, the operations of block 104 (forming an oxide layer) and block 106 (performing a clean process) may be repeated any number of times. Repeating blocks 104 and 106 may result in increased passivation and even further reducing or preventing outgassing of amines from the nitride structure.

Referring to block 108 of FIG. 1 and to FIG. 5, a photoresist is formed over the semiconductor substrate 202. The photoresist is formed with an opening that exposes at least part of the oxide layer. In the illustrated example, the photoresist is a photoresist 502 with the opening 504 exposing the oxide layer 402. The photoresist 502 is formed using photolithography. The photoresist 502 is deposited on the semiconductor substrate 202, such as by spin-on. The photoresist 502 is exposed to light (e.g., ultraviolet (UV) light) in a pattern corresponding to the opening 504. The photoresist 502 is then developed.

During the photolithography processing, the oxide layer 402 remains on the nitride gate spacers 302, which may reduce or prevent outgassing of amines from the nitride gate spacers 302 to thereby reduce or prevent poisoning of the photoresist 502 during that photolithography processing. Particularly, the photoresist may be a chemically amplified photoresist that may be patterned using deep UV light. In the absence of the oxide layer, amines may outgas from a nitride structure and poison the photoresist, which may cause a scum layer to be formed. For example, in a similar circumstance to what is illustrated in FIG. 5, a scum layer may be formed over the semiconductor substrate 202 (e.g., over and on the gate dielectric layer 220) between the nitride gate spacer 302 and a corresponding neighboring sidewall of the opening 504 in the photoresist 502 if the oxide layer 402 is not present. Such a scum layer may partially mask the semiconductor substrate 202 during a subsequent dopant implantation, which may prevent a target doping profile (including concentration) from being achieved.

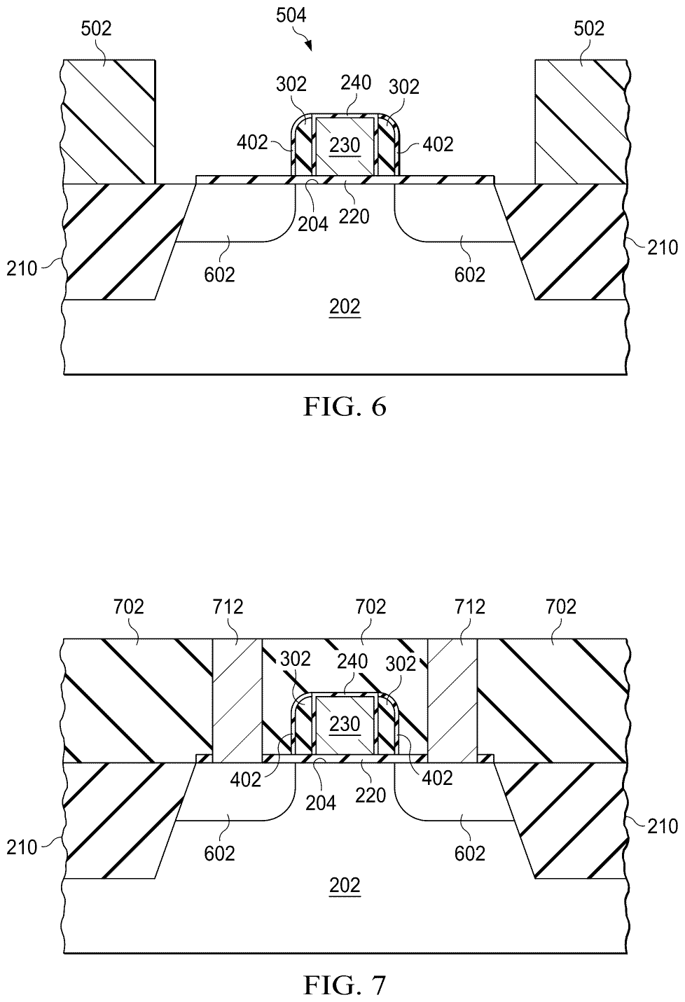

Referring to block 110 of FIG. 1 and to FIG. 6, a dopant implantation is performed using the patterned photoresist as a mask. The dopant implantation forms an implanted doped region in the semiconductor substrate 202 proximate to the nitride structure. The nitride structure may also act as a mask such that the implanted doped region is self-aligned with the nitride structure (e.g., a lateral boundary of the implanted doped region corresponds with a lateral edge of the nitride structure).

In the illustrated example of FIG. 6, the dopant implantation forms source/drain regions 602 in the semiconductor substrate 202. The source/drain regions 602 are on opposing lateral sides of the gate electrode 230 and nitride gate spacers 302. The gate electrode 230 and nitride gate spacers 302 (with oxide layer 402 thereon) also act as a mask during the dopant implantation such that the source/drain regions 602, as implanted in the semiconductor substrate 202, are self-aligned with the gate electrode 230 and nitride gate spacers 302 over the semiconductor substrate 202. If implemented, the LDD regions may be between the source/drain regions 602. For example, the LDD regions may underlie the respective nitride gate spacers 302. The dopant implantation implants p-type dopants (e.g., for a pFET) or n-type dopants (e.g., for an nFET) in the semiconductor substrate 202 corresponding to the opening 504 of the photoresist. A concentration of the p-type or n-type dopant of the source/drain regions 602 is greater than a concentration of the n-type dopant of the n-type doped well (if implemented), a concentration of the p-type or n-type dopant of the LDD regions (if implemented), and the p-type doped semiconductor substrate 202. In some examples, the source/drain regions 602 may be doped with a p-type or n-type dopant with a concentration in a range from 1×10¹⁹ cm⁻³ to 1×10²¹ cm⁻³.

In some examples, formation of a scum layer over the semiconductor substrate 202 (e.g., over and on the gate dielectric layer 220) between the nitride gate spacer 302 and a corresponding neighboring sidewall of the opening 504 in the photoresist 502 may be reduced or avoided due to the reduced or avoided outgassing of amines from the nitride gate spacer 302 by the presence of the oxide layer 402. Hence, a target doping profile (including concentration) of the implanted doped region(s) (e.g., the source/drain regions 602) may be more closely achieved. Achieving a target doping profile (including concentration), in some cases, may improve (e.g., reduce) an R_{DSON} of a FET.

Referring to block 112 of FIG. 1, the photoresist is removed. In the illustrated example of FIG. 6, the photoresist 502 is removed, such as by an ash process and/or wet strip process.

In FIG. 7, a FET is shown formed on the semiconductor substrate 202. Subsequent processing may be performed on the semiconductor substrate 202 following the dopant implantation. For example, as illustrated, a dielectric layer 702 is formed over the semiconductor substrate 202, the gate electrode 230, the nitride gate spacers 302, and the oxide layer 402. The dielectric layer 702 may include multiple sub-layers, such as a contact etch stop layer (CESL) conformally over the semiconductor substrate 202 and a pre-metal dielectric (PMD) layer over the CESL. The CESL may be or include silicon nitride, silicon oxynitride, the like, or a combination thereof. The PMD layer may be or include silicon oxide, silicon nitride, or the like. The dielectric layer 702 may be deposited using CVD, PECVD, ALD, or the like. The dielectric layer 702 may be planarized, such as by a CMP process.

Contacts 712 are formed to the source/drain regions 602. The contacts 712 extend through the dielectric layer 702 and, where present, the gate dielectric layer 220, and contact respective source/drain regions 602. The contacts 712 may each include one or more barrier and/or adhesion layers (e.g., titanium nitride (TiN), tantalum nitride (TaN), the like, or a combination thereof) conformally in a respective opening through the dielectric layer 702 and the gate dielectric layer 220, and a fill metal (e.g., tungsten (W), copper (Cu), aluminum (Al), the like, or a combination thereof) over and/or on the barrier and/or adhesion layer(s).

To form the contacts 712, respective openings may be formed through the dielectric layer 702 and the gate dielectric layer 220 to the source/drain regions 602 in the semiconductor substrate 202 using appropriate photolithography and etching processes. A metal(s) of the contacts 712 are deposited in the openings through the dielectric layer 702. The metal(s) may be deposited using an appropriate deposition process(es), such as CVD, physical vapor deposition (PVD), or the like. Any excess metal(s) may be removed, such as by a CMP and/or by patterning using photolithography and etch processes. Subsequent back-end-of-the-line (BEOL) processing may thereafter be performed.

As illustrated in FIG. 7, a semiconductor device may include the oxide layer 402 (or a portion thereof). In some examples, the oxide layer 402 is not removed and remains in a manufactured semiconductor device. Hence, as illustrated, the dielectric layer 702 (e.g., a sub-layer thereof, such as a CESL) is on and contacts the oxide layer 402, which is on the nitride gate spacers 302.

In other examples, the oxide layer 402 may be removed during other semiconductor processing. For example, in some examples, a cleaning process prior to a silicidation process may remove oxide including the oxide layer 402. For example, after the removal of the photoresist 502, a cleaning process may be performed, which removes the oxide layer 402, exposed portions of the reoxidation layer 240, and exposed portions of the gate dielectric layer 220. Removing the oxide exposes an upper surface of the gate electrode 230 and the upper surface 204 of the semiconductor substrate 202 where the source/drain regions 602 are formed. A metal (e.g., Ni, Ti, Co, Pt) may be deposited over the semiconductor substrate 202, such as by PVD, CVD, or the like. The metal is reacted with a semiconductor material, such as the semiconductor material of the semiconductor substrate 202 and the semiconductor material of the gate electrode 230, if so implemented. An anneal process may be used to cause the metal to react with a semiconductor material. Any unreacted metal may be removed, such as by an etch selective to the metal. This may form a silicide on the semiconductor substrate 202 where the source/drain regions 602 are formed and on the gate electrode 230. The dielectric layer 702 may thereafter be formed, and the contacts 712 may be formed to the silicide on the source/drain regions 602.

As illustrated by FIG. 7, a FET includes the gate electrode 230, the gate dielectric layer 220 underlying the gate electrode 230, the source/drain regions 602 in the semiconductor substrate 202, LDD regions (if implemented) in the semiconductor substrate 202, and a channel region in the semiconductor substrate 202. The channel region underlies (e.g., directly underlies) the gate electrode 230 and the gate dielectric layer 220. The channel region may be between the LDD regions and is between the source/drain regions 602. One LDD region may be between the channel region and a corresponding source/drain region 602, and the other LDD region may be between the channel region and the other source/drain region 602. The nitride gate spacers 302 are along respective sidewalls of the gate electrode 230, and in some examples, such as illustrated, the oxide layer 402 is on the nitride gate spacers 302, as described above. If the FET is a pFET, the source/drain regions 602 and LDD regions, if implemented, may be p-type doped, and the pFET may further include an n-type doped well in the semiconductor substrate 202, where the source/drain regions 602 and LDD regions are in the n-type doped well. If the FET is an nFET, the source/drain regions 602 and LDD regions, if implemented, may be p-type doped.

Some examples may achieve improved source-to-drain on resistance (R_{DSON}) of a FET. Forming an oxide layer on a nitride gate spacer may reduce or prevent outgassing of amines that poison the photoresist used as a mask for dopant implantation (e.g., to form source/drain regions). Poisoning the photoresist can form a scum layer on the semiconductor substrate, which can prevent the dopant implantation from achieving a target doping profile (including concentration) in the semiconductor substrate. Reducing or preventing such photoresist poisoning may reduce or avoid formation of a scum layer such that the dopant implantation may more closely achieve a target doping profile (including concentration). In some examples, a 1% to 2% improvement in R_{DSON} has been observed in FETs (e.g., laterally diffused metal-oxide-semiconductor (LDMOS) FETs) manufactured using processing described above. In further examples, a 3% to 5% improvement in R_{DSON} has been observed in FETs (e.g., LDMOS FETs) manufactured using processing described above. Additionally, a critical dimension (CD) for the photoresist patterning may be reduced, such as 19% in observed examples.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a nitride structure over the semiconductor substrate; and
an oxide layer on the nitride structure, wherein the semiconductor substrate includes an implanted doped region laterally proximate the nitride structure and the oxide layer.

2. The semiconductor device of claim 1, further comprising:
a gate dielectric layer over the semiconductor substrate; and
a gate electrode over the gate dielectric layer, wherein:
the nitride structure is a nitride spacer along a sidewall of the gate electrode;
the oxide layer is on a surface of the nitride spacer facing away from the gate electrode; and
the implanted doped region is a source/drain region in the semiconductor substrate.

3. A method, comprising:
forming a nitride structure over a semiconductor substrate;
forming an oxide layer on the nitride structure;
forming a photoresist over the semiconductor substrate, the photoresist having an opening exposing at least a portion of the oxide layer on the nitride structure; and
performing an implantation using the photoresist to form an implanted doped region in the semiconductor substrate.

4. The method of claim 3, wherein forming the oxide layer includes performing an oxidation process.

5. The method of claim 4, wherein the oxidation process is an ash process.

6. The method of claim 4, wherein the oxidation process is a thermal oxidation.

7. The method of claim 3, wherein forming the oxide layer includes depositing the oxide layer.

8. The method of claim 3, further comprising performing a cleaning process on the oxide layer before forming the photoresist.

9. The method of claim 8, wherein the cleaning process includes a sulfuric acid and peroxide mixture (SPM).

10. The method of claim 8, wherein the cleaning process includes an RCA clean 1 (SC1).

11. The method of claim 10, wherein the RCA SC1 is performed at a temperature in a range from 21° C. to 27° C.

12. The method of claim 8, wherein the cleaning process includes a sulfuric acid and peroxide mixture (SPM) and an RCA clean 1 (SC1) following the SPM.

13. The method of claim 3, further comprising forming a gate electrode over the semiconductor substrate, wherein:
the nitride structure is a gate spacer formed along a sidewall of the gate electrode;
the oxide layer is formed on a surface of the gate spacer facing away from the gate electrode; and
the implanted doped region is a source/drain region laterally proximate to the gate spacer.

14. A method, comprising:
forming a gate electrode over a semiconductor substrate;
forming a nitride gate spacer over the semiconductor substrate and along a sidewall of the gate electrode;
forming an oxide layer on the nitride gate spacer;
forming a photoresist over the semiconductor substrate, the photoresist having an opening exposing at least a portion of the oxide layer on the nitride gate spacer; and
forming a source/drain region in the semiconductor substrate, forming the source/drain region comprising performing an implantation of a dopant into the semiconductor substrate using the photoresist.

15. The method of claim 14, wherein forming the oxide layer includes performing an oxidation process, the oxidation process including an ash process, a thermal oxidation, or a combination thereof.

16. The method of claim 14, wherein forming the oxide layer includes depositing the oxide layer.

17. The method of claim 14, further comprising performing a cleaning process on the oxide layer before forming the photoresist.

18. The method of claim 17, wherein the cleaning process includes a sulfuric acid and peroxide mixture (SPM).

19. The method of claim 17, wherein the cleaning process includes an RCA clean 1 (SC1).

20. The method of claim 17, wherein the cleaning process includes a sulfuric acid and peroxide mixture (SPM) and an RCA clean 1 (SC1) following the SPM.
